(19) United States
(12) Patent Application Publication
(10) Pub. No.: US 2026/0173920 A1
(43) Pub. Date: Jun. 18, 2026

(54) SEMICONDUCTOR MEMORY PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/365,205

(22) Filed: Oct. 22, 2025

(30) Foreign Application Priority Data
Dec. 18, 2024 (TW) 113149411

(51) Int. Cl. H01L 23/00; H01L 23/498

(52) U.S. Cl. CPC H10W 70/635; H10W 70/65; H10W 70/09; H10W 70/093; H10W 70/60; H10W 70/6528; H10W 90/00

(57) ABSTRACT

A semiconductor memory packaging unit is provided. The semiconductor memory packaging unit includes a chip package, a plurality of first connecting bodies, and a substrate. The chip package is further provided with a redistribution layer (RDL) composed of a dielectric layer and a plurality of conductive circuits. The conductive circuits are electrically connected to a plurality of die pads on a chip of the chip package. A circuit layout space on the die pads of the chip package is improved by the RDL. Thereby a layout of pads for connecting the conductive circuit with the outside can be adjusted. Therefore, the layout of circuits is easy for manufacturers to prevent the circuits from too dense and this helps reduction of production cost and improves reliability and yield rate of products.

### CROSS-REFERENCE TO RELATED APPLICATIONS

This non-provisional application claims priority under 35 U.S.C. § 119(a) on Patent Application No(s). 113149411 filed in Taiwan, R.O.C. on Dec. 18, 2024, the entire contents of which are hereby incorporated by reference.

### BACKGROUND OF THE INVENTION

The present invention relates to a semiconductor memory packaging unit, especially to a chip package of a semiconductor memory packaging unit added with at least one redistribution layer (RDL).

Refer to FIG. 8-11, a schematic drawing showing conventional standardized structure of a semiconductor memory packaging unit 1a is provided. The semiconductor memory packaging unit 1a includes a chip package 10a, a plurality of first connecting bodies 40a, and a substrate 50a. The chip package 10a consists of a chip 11a and an insulating layer 30a. The chip 11a is provided with a first surface 12a and a plurality of die pads 13a on the first surface 12a. The insulating layer 30a is located at the chip 11a and covering the chip 11a. The insulating layer 30a includes a first surface 31a and a plurality of first openings 32a. A copper pillar 321a is mounted in the first opening 32a for allowing the die pad 13a of the chip 11a to be electrically connected to the outside. A part of the respective first connecting bodies 40a is disposed in the first opening 32a of the insulating layer 30a. The first connection body 40a is electrically connected to the die pad 13a of the chip 11a by the copper pillar 321a. The substrate 50a is located at the first surface 31a of the insulating layer 30a and the respective first connecting bodies 40a and having a first surface 51a and a second surface 52a opposite to the first surface 51a. The first surface 51a and the second surface 52a are respectively provided with a first protective layer 53a and a second protective layer 54a. The first protective layer 53a is provided with a plurality of second openings 55a each of which is mounted with a first circuit 56a therein. The first circuit 56a is used for electrical connection to the outside by a second connection body 60a (such as a solder ball). The second protective layer 54a is provided with a plurality of third openings 57a each of which is mounted with a second circuit 58a therein. A part of the first connection body 40a is mounted in the third openings 57a and the first connection body 40a is electrically connected to the second circuit 58a. A conductive pillar 59a is arranged between the first circuit 56a and the second circuit 58a and electrically connected to the first circuit 56a and the second circuit 58a. In order to explain structural relationship between the respective components more clearly, the number of the die pad 13a, the first opening 32a, the copper pillar 321a, the first connection body 40a, the second opening 55a, the first circuit 56a, the third opening 57a, the second circuit 58a, and the conductive pillar 59a in the embodiment in FIG. 8 is only one.

Refer to FIG. 8, a thickness of the standardized structure of the conventional semiconductor memory packaging unit 1a is as follows. The copper pillar 321a, the first connection body 40a, the first protective layer 53a, the second circuit 58a, the conductive pillar 59a, the substrate 50a, and the first circuit 56 a respectively have a thickness of 50 um, 20 um, 30 um, 25 um, 75 um, 75 um, and 25 um. A thickness of a connection body formed by the solder ball on the first circuit 56a for connection to the outside is 350 um.

Refer to FIG. 9, a schematic drawing showing a chip side up of the chip package 10a is provided. The chip size is 9963 um×7498 um. The minimum die pad size 13 a on the chip 11 a is 50 um×60 um. The minimum space between the die pads 13 is 30 um.

Refer to FIG. 10, a schematic drawing showing a top view of the substrate 50a (SBT Top View) is provided. It's package outline drawing (POD) is 11000 um×9000 um. The minimum distance between the second circuits 58 a on the second surface 52 a (min. space) is 30 um. The minimum line width of the second circuit 58 a is 30 um. The laser size is 200 um. The laser pad size is 100 um.

Refer to FIG. 11, a schematic drawing showing a bottom view of the substrate 50a (SBT Bottom View) is provided. The minimum distance (min. space) between the first circuits 56a on the first surface 51a of the substrate 50 a is 30 um. The minimum line width of the first circuit 56 a is 30 um. The number of the solder balls arranged (ball counts) is 78. A size of the ball (ball size) electrically connected to the first circuit 56 a is 500 um. The minimum distance between the solder balls (min. ball pitch) is 800 um.

According to the above descriptions, the standardized structure of the semiconductor memory packaging unit 1a available now has the following shortcomings and problems. The circuit layout on the chip package 10a is too dense and thus difficult to be designed (as shown in FIG. 9). This makes layout on the substrate 50a (as shown in FIG. 10) electrically connected to the chip package 10a is relatively dense. The second surface 52a (as shown in FIG. 11) of the substrate 50a for electrical connection to the outside also has the same problem. Thus production cost of the substrate (such as printed circuit board) is increased relatively. Moreover, the dense circuit increases production cost of manufacturers due to difficulty in the design. Inaccurate welding also occurs so that reliability and yield rate of the products are reduced.

### SUMMARY OF THE INVENTION

Therefore, it is a primary object of the present invention to provide a semiconductor memory packaging unit which includes a chip package, a plurality of first connecting bodies, and a substrate. The chip package includes a redistribution layer (RDL) composed of a dielectric layer and a plurality of conductive circuits. The conductive circuits are electrically connected to a plurality of die pads on a chip of the chip package. A layout design of the conductive circuit on the chip package for connection to the outside is improved by RDL process. Then the semiconductor memory packaging unit is formed by molding and packaging. Thereby a distance between the circuits is increased and shortcomings and problems caused by standardized structure of the semiconductor memory packaging units available now can be solved effectively.

In order to achieve the above object, a semiconductor memory packaging unit according to the present invention includes a chip package, a plurality of first connecting bodies, and a substrate. The chip package consists of a chip and an insulating layer. The chip includes a first surface and a plurality of die pads on the first surface. The insulating layer is located over and covering the chip. The insulating layer includes a first surface and a plurality of first openings each of which allows the corresponding die pad of the chip to have electrical connection with the outside. A part of the first connection body is mounted in the first opening of the insulating layer while the first connection body is electrically connected to the die pad of the chip. The substrate is located at the first surface of the insulating layer and the first connection body and composed of a first surface and a second surface opposite to the first surface. The first surface and the second surface of the substrate are respectively provided with a first protective layer and a second protective layer. The first protective layer is provided with a plurality of second openings each of which is mounted with a first circuit therein. The first circuit is used for electrical connection to the outside. The second protective layer is provided with a plurality of third openings each of which is mounted with a second circuit therein. A part of the first connection body is mounted in the third opening and the first connection body is electrically connected to the second circuit. A conductive pillar is arranged between the first circuit and the second circuit and electrically connected to the first circuit and the second circuit. The semiconductor memory packaging unit further includes a RDL layer produced by RDL process. The RDL layer is disposed between the chip and the insulating layer and covered by the insulating layer. The RDL includes a dielectric layer and a plurality of conductive circuits. The dielectric layer is provided with a first surface and a plurality of grooves for allowing the die pads of the chip to be exposed. The first surface of the dielectric layer is disposed on the first surface of the chip correspondingly. The conductive circuit is mounted in the grooves correspondingly and electrically connected to the die pad. The conductive circuits are made of metals. The chip of the semiconductor memory packaging unit is electrically connected to the outside through the die pad, the conductive circuit, the first connection body, the second circuit, the conductive pillar, and the first circuit in turn.

Preferably, the conductive circuit exposed through the first opening is welded to the outside by a solder ball. After welding, the solder ball is located in both the first opening and the third opening at the same time to form the first connection body.

Preferably, the first circuit in the second opening of the substrate is welded to the outside by a solder ball. After welding, the solder ball forms a second connection body on the first circuit in the second opening.

Preferably, the die pad, the dielectric layer, the conductive circuit, the first connection body, the substrate, the first outer protective layer, the second outer protective layer, the first circuit, the second circuit, the conductive pillar, and the second connection body respectively have a thickness of 2 um, 10 um, 10 um, 50 um, 135 um, 30 um, 30 um, 25 um, 25 um, 75 um, and 350 um.

Preferably, the conductive circuit is made of silver (Ag) while the first circuit, the second circuit, and the conductive pillar are made of copper (Cu).

Preferably, the semiconductor memory packaging unit is disposed on a printed circuit board (PCB).

Preferably, a memory of the semiconductor memory packaging unit includes dynamic random-access memory (DRAM), static random-access memory (SRAM), and synchronous dynamic random-access memory (SDRAM).

### BRIEF DESCRIPTION OF THE DRAWINGS

FIG. 1 is a side sectional view of a semiconductor memory packaging unit of an embodiment according to the present invention;

FIG. 2 is a side sectional view showing connection of a chip package with a substrate of an embodiment according to the present invention;

FIG. 3 is a side sectional view showing arrangement of a solder ball at a semiconductor memory packaging unit of an embodiment according to the present invention;

FIG. 4 is a plan view of a first surface of an insulating layer of a chip package of an embodiment according to the present invention;

FIG. 5 is a partial enlarged view of the embodiment in FIG. 4 according to the present invention;

FIG. 6 is a plan view of a second surface of a substrate of an embodiment according to the present invention;

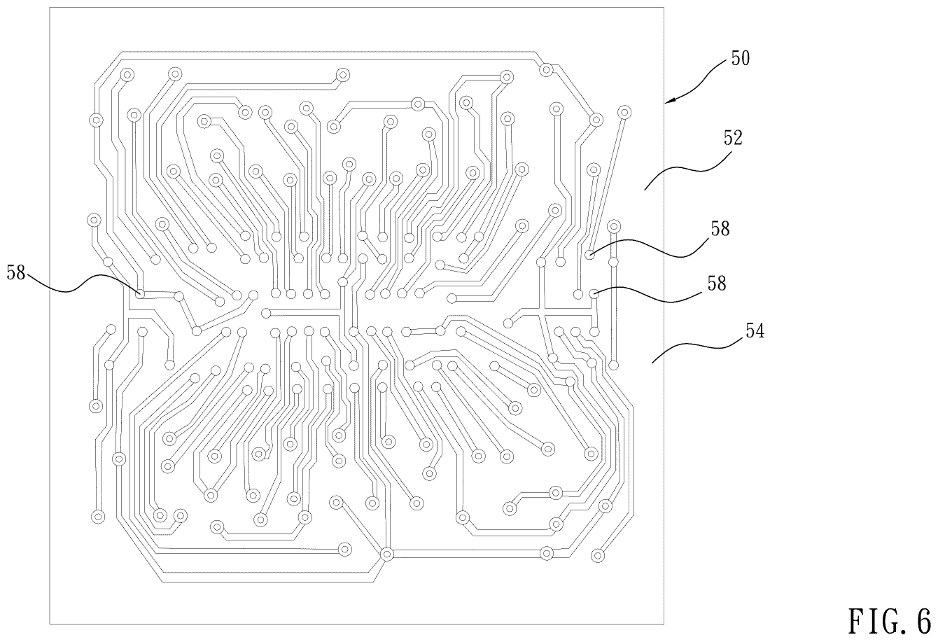

FIG. 7 is a partial enlarged view of the embodiment in FIG. 6 according to the present invention;

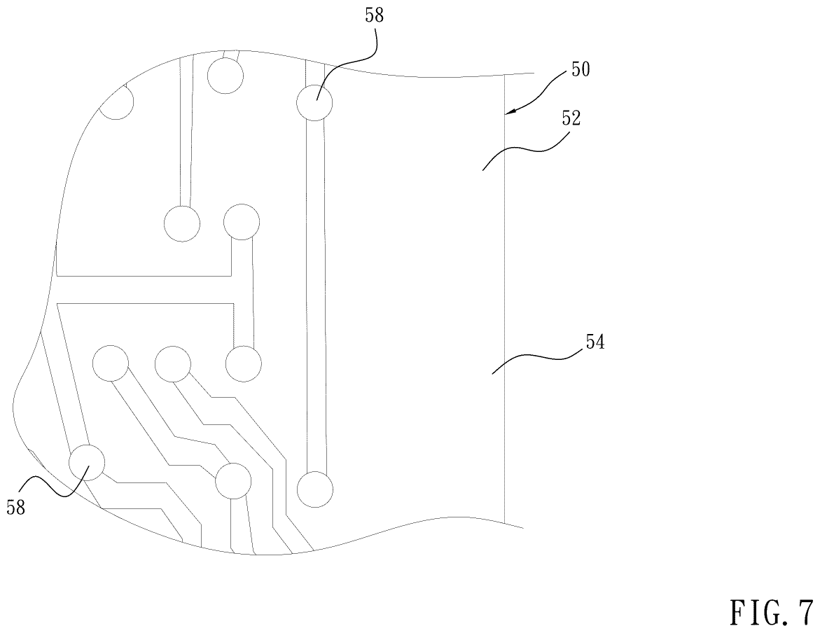

FIG. 8 is a side sectional view of a semiconductor memory packaging unit available now;

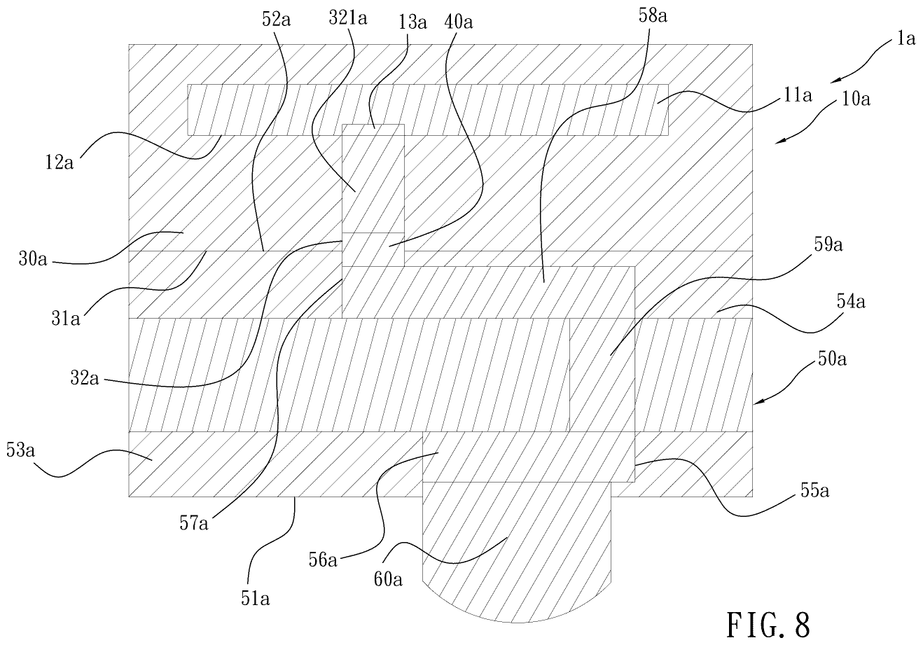

FIG. 9 is a plan view of a first surface of an insulating layer of a chip package available now;

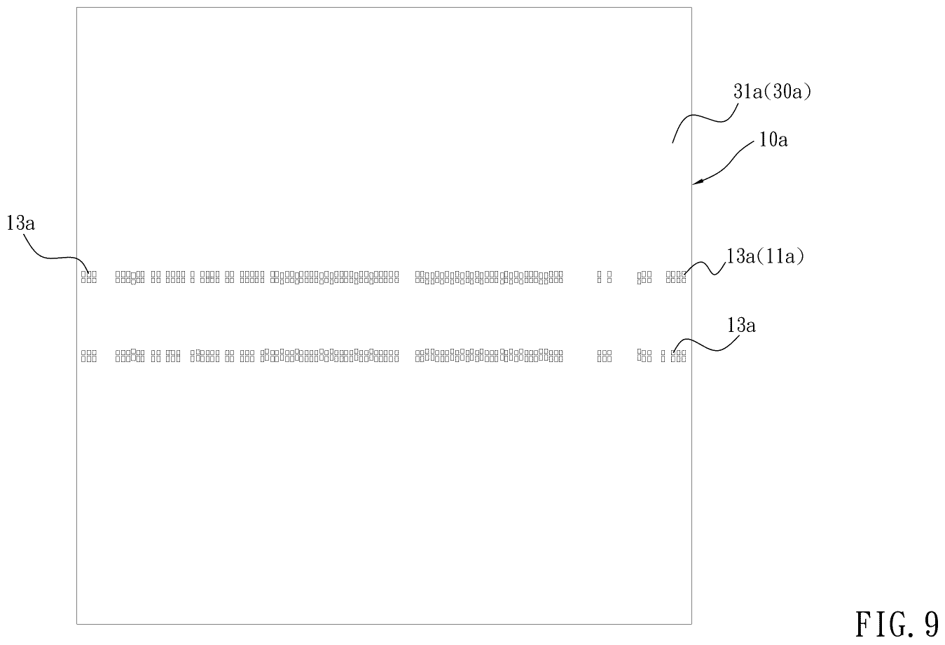

FIG. 10 is a plan view of a second surface of a substrate available now;

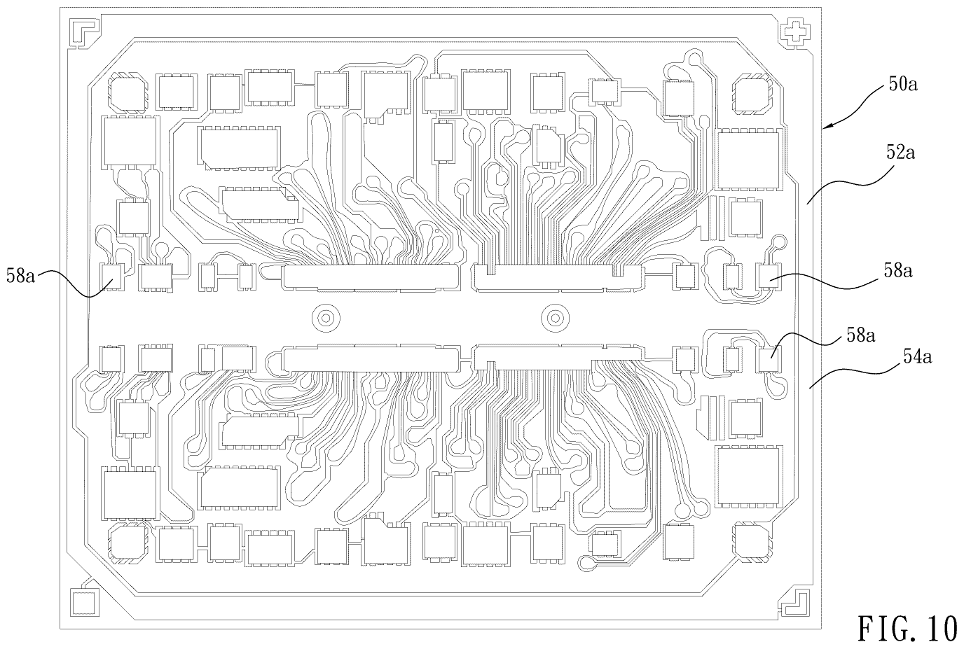

FIG. 11 is a plan view of a first surface of a substrate available now.

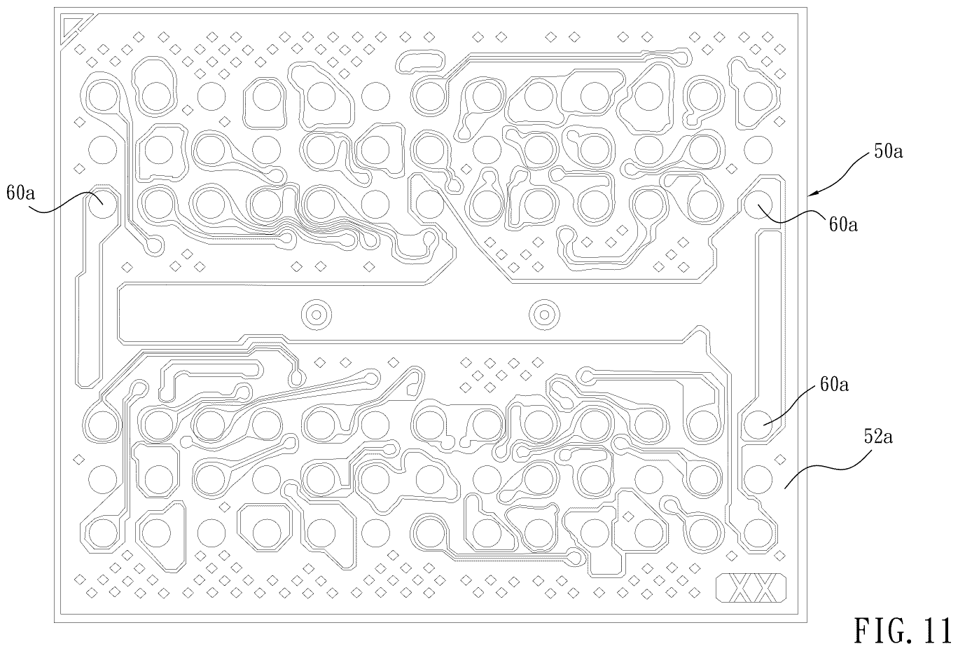

### DETAILED DESCRIPTION OF THE PREFERRED EMBODIMENT

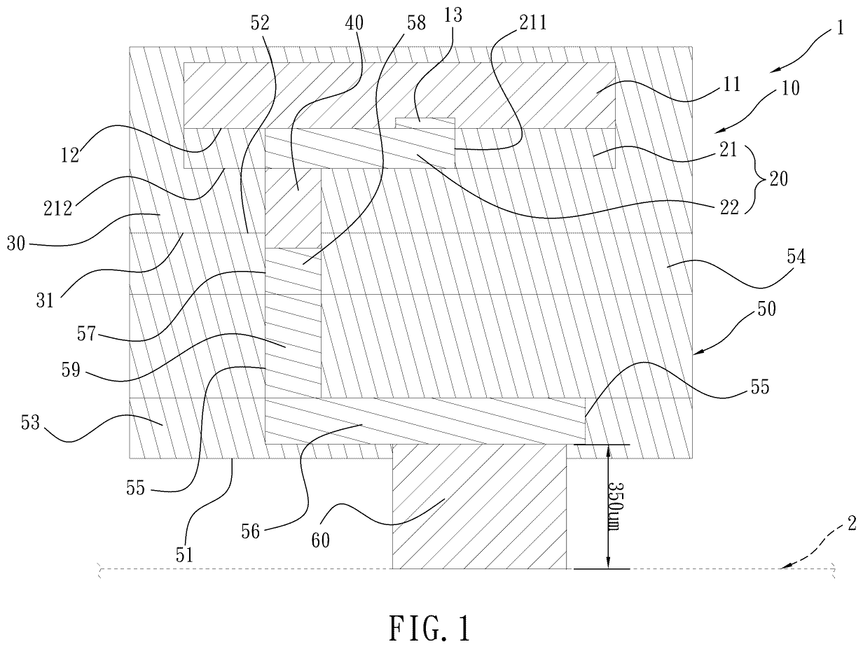

Refer to FIG. 1, a semiconductor memory packaging unit 1 is provided by the present invention. The semiconductor memory packaging unit 1 includes a chip package 10, a plurality of first connecting bodies 40, and a substrate 50. The chip package 10 is combined with the substrate 50 by the first connecting bodies 40 to form the semiconductor memory packaging unit 1.

As shown in FIG. 1, the chip package 10 consists of a chip 11, a redistribution layer (RDL) 20, and an insulating layer 30. The chip 11 has a first surface 12 and a plurality of die pads 13 on the first surface 12. The RDL 20 which is produced by a RDL fabrication process is disposed between the chip 11 and the insulating layer 30 and covered by the insulating layer 30. The RDL 20 includes a dielectric layer 21 and a plurality of conductive circuits 22. The dielectric layer 21 is provided with a first surface 211 and a plurality of grooves 212 for allowing the die pads 13 of the chip 11 to be exposed The first surface 211 of the dielectric layer 21 is disposed on the first surface 12 of the chip 11 correspondingly. The conductive circuits 22 are mounted in the grooves 212 correspondingly and electrically connected to the die pads 13. The conductive circuits 22 are made of metals. The insulating layer 30 is located over and covering the chip 11 and provided with a first surface 31 and a plurality of first openings 32 each of which allows the die pad 13 of the chip 11 to have electrical connection with the outside.

Refer to FIG. 1, a part of the first connection body 40 is mounted in the first opening 32 of the insulating layer 30 while the first connection body 40 is electrically connected to the die pad 13 of the chip 11.

Refer to FIG. 1, the substrate 50 is located at the first surface 31 of the insulating layer 30 and the respective first connecting bodies 40 and composed of a first surface 51 and a second surface 52 opposite to the first surface 51. The first surface 51 and the second surface 52 of the substrate 50 are respectively provided with a first protective layer 53 and a second protective layer 54. The first protective layer 53 is provided with a plurality of second openings 55 each of which is mounted with a first circuit 56 therein. The first circuit 56 is used for electrical connection to the outside. The second protective layer 54 is provided with a plurality of third openings 57 each of which is mounted with a second circuit 58 therein. A part of the first connection body 40 is mounted in the third opening 57 and the first connection body 40 is electrically connected to the second circuits 58. A conductive pillar 59 is arranged between the first circuit 56 and the second circuit 58 and electrically connected to the first circuit 56 and the second circuit 58.

Refer to FIG. 1, the chip 11 of the semiconductor memory packaging unit 1 is electrically connected to the outside through the die pad 13, the conductive circuit 22, the first connection body 40, the second circuit 58, the conductive pillar 59, and the first circuit 56 in turn.

In order to explain structural relationship between the respective components easier and more clearly, the number of the die pad 13, the first opening 32, the first connection body 40, the second opening 55, the first circuit 56, the third opening 57, the second circuit 58, and the conductive pillar 59 in the embodiment in FIG. 1 is only one. This is only an example for explanation, not intended to limit the present invention.

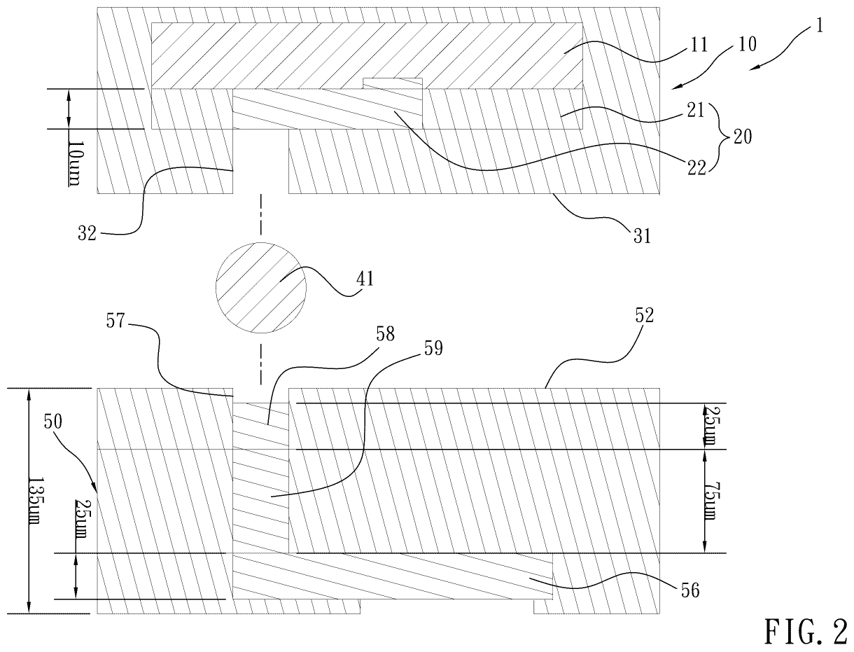

Refer to FIG. 2, the conductive circuit 22 exposed through the first opening 32 is welded to the outside by a solder ball 41. After welding, the solder ball 41 is located in the first opening 32 and the third opening 57 at the same time to form the first connection body 40, as shown in FIG. 1.

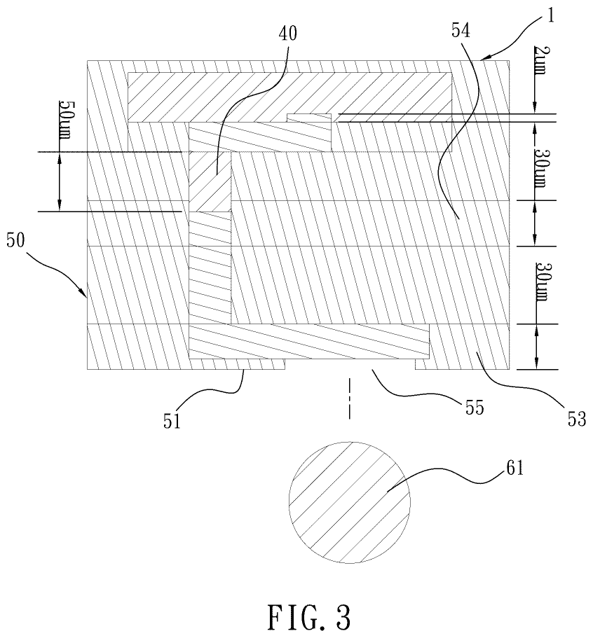

Refer to FIG. 3, the first circuit 56 in the second opening 55 of the substrate 50 is welded to the outside by a solder ball 61. After welding, the solder ball 61 forms a second connection body 60 on the first circuit 56 in the second opening 55 (as shown in FIG. 1). A thickness of the second connection body 60 is 350 um, as shown in FIG. 1.

The thickness of the respective component of the semiconductor memory packaging unit 1 is as follows, but not limited. The die pad 13, the dielectric layer 21, the conductive circuit 22, the first connection body 40, and the substrate 50 respectively have a thickness of 2 um (as shown in FIG. 3), 10 um (as shown in FIG. 2), 10 um (as shown in FIG. 2), 50 um (as shown in FIG. 3), and 135 um (as shown in FIG. 2). The first outer protective layer 53, the second outer protective layer 54, the first circuit 56, the second circuit 58, and the conductive pillar 59 respectively have a thickness of 30 um (as shown in FIG. 3), 30 um (as shown in FIG. 3), 25 um (as shown in FIG. 2), 25 um (as shown in FIG. 2), and 75 um (as shown in FIG. 2),

Refer to FIG. 1, the conductive circuit 22 is made of silver (Ag) while the first circuit 56, the second circuit 58, and the conductive pillar 59 are made of copper (Cu).

Refer to FIG. 1, the semiconductor memory packaging unit 1 is disposed on a printed circuit board (PCB).

Refer to FIG. 1, a memory of the semiconductor memory packaging unit 1 includes dynamic random-access memory (DRAM), static random-access memory (SRAM), and synchronous dynamic random-access memory (SDRAM).

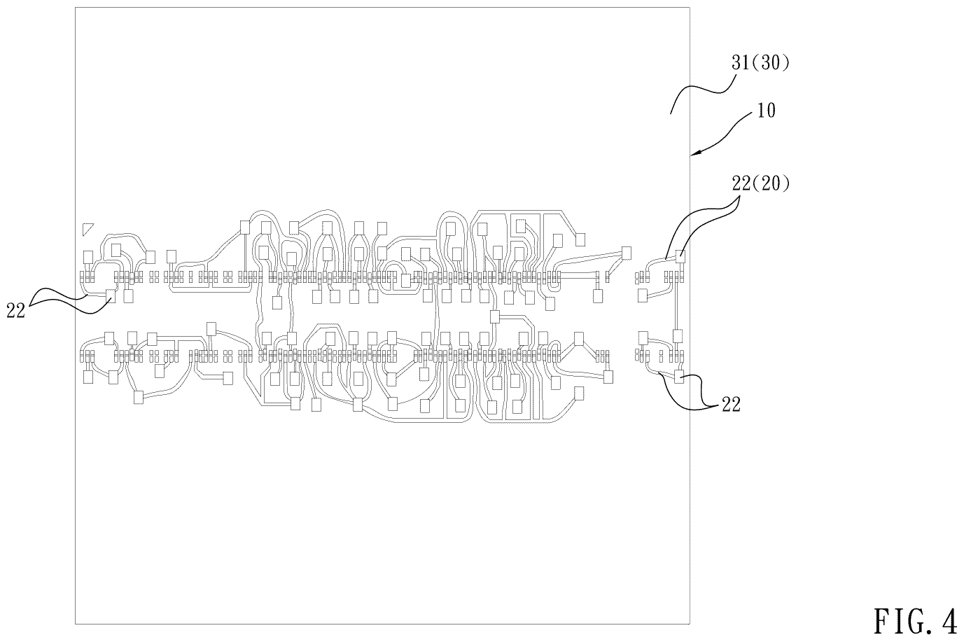

Refer to FIG. 4, a chip size of the chip package 10 is 9963 um×7498 um. The minimum pad size of an area of the conductive circuit connected to the outside (called pad) is 60 um×149.8 um. The minimum distance between the areas of the conductive circuit 22 connected to the outside (called pad) (min. space, die pad to die pad) is 20 um. The minimum width of the conductive circuit 22 is 40 um. The die alignment parameter (L2F-DIE Align.) is 5 um. A size of the solder ball (ball size) able to be electrically connected to the conductive circuit 22 is 170 um and the number of the solder balls is 90 while the minimum distance between the solder balls (min. ball pitch) is 300 um.

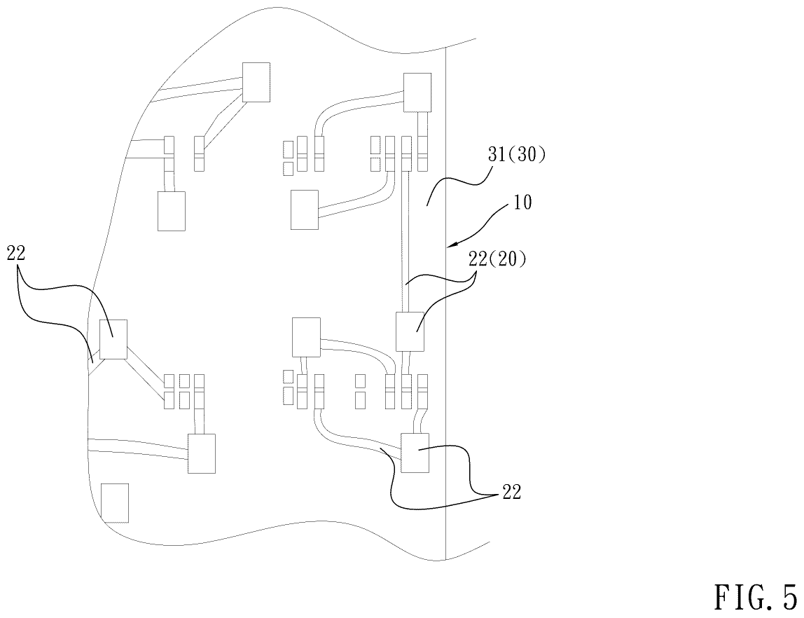

Refer to FIG. 5, a package outline drawing (POD) of the substrate 50 is 11000 um×9000 um. The minimum distance (min space) between the second circuits 58 on the second surface 52 is 70 um. The min. line width of the second circuit 58 is 70 um. The laser size and the laser pad size are respectively 127 um and 250 um.

In practice of manufacturing the semiconductor memory packaging unit available now, a production cost of a part of components (such as printed circuit board (PCB)) in standardized structure of the conventional semiconductor memory packaging unit is about 0.6 US dollars. As to the production cost of related part of components (such as RDL 20 and PCB 2) corresponding to the present semiconductor memory packaging unit 1 is about 0.3 US dollars. Although the present invention further includes manufacturing of the RDL 20, the cost of the present semiconductor memory packaging unit 1 is only a half of the conventional one.

A method of manufacturing the semiconductor memory packaging unit 1 according to the present invention includes the following steps.

Step S1: providing a chip 11, as shown in FIG. 1. The chip 11 has a first surface 12 and a plurality of die pads 13 on the first surface 12.

Step S2: arranging a RDL 20 over the first surface 12 of the chip 11 by RDL manufacturing process, as shown in FIG. 1. The RDL 20 includes a dielectric layer 21 and a plurality of conductive circuits 22. The dielectric layer 21 is provided with a dielectric layer 21 and a plurality of grooves 212. The first surface 211 is disposed on the first surface 12 of the chip 11 correspondingly and the grooves 212 are used for allowing the die pads 13 of the chip 11 to be exposed. The conductive circuits 22 are mounted in the grooves 212 correspondingly and electrically connected to the die pads 13.

Step S3: disposed an insulating layer 30 over the chip 11 and the RDL 20 for covering both the chip 11 and the RDL 20 to form a chip package 10. The insulating layer 30 includes a first surface 31 and a plurality of first openings 32 each of which allows the die pad 13 of the chip 11 to have electrical connection with the outside.

Step S4: providing a substrate 50, as shown in FIG. 1. The substrate 50 is composed of a first surface 51 and a second surface 52 which are opposite to each other and respectively provided with a first protective layer 53 and a second protective layer 54. The first protective layer 53 is provided with a plurality of second openings 55 each of which is mounted with a first circuit 56 therein. The first circuit 56 is used for electrical connection to the outside. The second protective layer 54 is provided with a plurality of third openings 57 each of which is mounted with a second circuit 58 therein. A conductive pillar 59 is arranged between the first circuit 56 and the second circuit 58 and electrically connected to the first circuit 56 and the second circuit 58.

Step S5: using a plurality of solder balls 40a to electrically connect the chip package 10 with the substrate 50 into one part, as shown in FIG. 2. After welding, the solder balls 40a form a plurality of first connecting bodies 40 between the chip package 10 and the substrate 50, as shown in FIG. 1. Thereby a semiconductor memory packaging unit 1 is formed. A part of the first connection body 40 is mounted in the first opening 32 of the insulating layer 30 while the first connection body 40 is electrically connected to the die pad 13 of the chip 11. A part of the first connection body 40 is mounted in the third opening 57 and the first connecting bodies 40 are electrically connected to the second circuits 58. The chip 11 of the semiconductor memory packaging unit 1 is electrically connected to the outside through the die pad 13, the conductive circuit 22, the first connection body 40, the second circuit 58, the conductive pillar 59, and the first circuit 56 in turn.

According to the step S2, it is learned that the RDL 20 is formed and extending horizontally on the surface of the chip 11 by the RDL manufacturing process. Since the RDL 20 is a process easy to be implemented precisely, the manufacturing process is more simplified. The semiconductor memory packaging unit 1 achieves a light weight and compact design under condition that the redistribution circuits 20 still have electrical extension in the XY plane and interconnections.

Compared with the semiconductor memory packaging unit available now, the semiconductor memory packaging unit 1 according to the present invention has the following advantages.
(1) The respective die pads 13 are connected to the outside by the conductive circuits 22 produced by the RDL process and redistributed. Thus layout design between the areas of the conductive circuit 22 connected to the outside (called pads) becomes more diversified.
(2) A circuit layout space on the chip package 10 is quite flexible and easy to design. Thus a circuit layout on the substrate 50 electrically connected with the chip package 10 is also relatively flexible and easy to design and this helps production cost reduction for manufacturers.
(3) The circuit layout on the chip package 10 is relatively flexible so that the circuits are not too dense. Thus the welding process is more precise and successful. This helps improvement in product reliability and yield rate.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent

1. A semiconductor memory packaging unit comprising:
a chip package, a plurality of first connecting bodies, and a substrate;
wherein the chip package includes a chip and an insulating layer; the chip includes a first surface and a plurality of die pads on the first surface; the insulating layer is located over the chip and covering the chip; the insulating layer is provided with a first surface and a plurality of first openings each of which allows the die pad of the chip to have electrical connection with the outside; wherein a part of the first connection body is mounted in the first opening of the insulating layer while the first connection body is electrically connected to the die pad of the chip;
wherein the substrate is located at the first surface of the insulating layer and the first connection body and composed of a first surface and a second surface opposite to the first surface; the first surface and the second surface of the substrate are respectively provided with a first protective layer and a second protective layer; the first protective layer is provided with a plurality of second openings each of which is mounted with a first circuit therein; the first circuits are used for electrical connection to the outside; the second protective layer is provided with a plurality of third openings each of which is mounted with a second circuit therein; wherein a part of the first connection body is mounted in the third opening and the first connection body is electrically connected to the second circuit; wherein a conductive pillar is arranged between the first circuit and the second circuit and electrically connected to the first circuit and the second circuit; the semiconductor memory packaging unit is characterized in that the semiconductor memory packaging unit further includes a redistribution layer (RDL) layer produced by RDL process; the RDL layer is disposed between the chip and the insulating layer and covered by the insulating layer; the RDL includes a dielectric layer and a plurality of conductive circuits; wherein the dielectric layer having a first surface and a plurality of grooves used for allowing the die pads of the chip to be exposed; the first surface disposed on the first surface of the chip correspondingly;
wherein the conductive circuit is mounted in the groove correspondingly and electrically connected to the die pad; wherein the conductive circuits are made of metals; wherein the chip of the semiconductor memory packaging unit is electrically connected to the outside through the die pad, the conductive circuit, the first connection body, the second circuit, the conductive pillar, and the first circuit in turn.

2. The semiconductor memory packaging unit as claimed in claim 1, wherein the conductive circuit exposed through the first opening is welded to the outside by a solder ball; after welding, the solder ball is located in both the first opening and the third opening at the same time to form the first connection body.

3. The semiconductor memory packaging unit as claimed in claim 1, wherein the first circuit in the second opening of the substrate is welded to the outside by a solder ball; after welding, the solder ball forms a second connection body on the first circuit in the second opening.

4. The semiconductor memory packaging unit as claimed in claim 1, wherein the die pad, the dielectric layer, the conductive circuit, the first connection body, the substrate, the first outer protective layer, the second outer protective layer, the first circuit, the second circuit, the conductive pillar, and the second connection body respectively have a thickness of 2 um, 10 um, 10 um, 50 um, 135 um, 30 um, 30 um, 25 um, 25 um, 75 um, and 350 um.

5. The semiconductor memory packaging unit as claimed in claim 1, wherein the conductive circuit is made of silver (Ag) while the first circuit, the second circuit, and the conductive pillar are made of copper (Cu).

6. The semiconductor memory packaging unit as claimed in claim 1, wherein the semiconductor memory packaging unit is disposed on a printed circuit board (PCB).

7. The semiconductor memory packaging unit as claimed in claim 1, wherein a memory of the semiconductor memory packaging unit includes dynamic random-access memory (DRAM), static random-access memory (SRAM), and synchronous dynamic random-access memory (SDRAM).
